(19) United States
(12) Patent Application Publication
(10) Pub. No.: US 2024/0079233 A1
(43) Pub. Date: Mar. 7, 2024

(54) MEMBER, TRANSISTOR DEVICES, POWER DEVICES, AND METHOD FOR MANUFACTURING MEMBER

(71) Applicant: HUAWEI TECHNOLOGIES CO., LTD., Shenzhen (CN)

(72) Inventors: Gilberto Curatola, Nuremberg (DE); Marco Silvestri, Munich (DE)

(21) Appl. No.: 18/509,050

(22) Filed: Nov. 14, 2023

Related U.S. Application Data
(63) Continuation of application No. PCT/EP2021/070466, filed on Jul. 22, 2021.

(51) Int. Cl. H01L 21/02; H01L 27/06; H01L 29/24; H01L 29/78; H01L 29/812; H01L 29/872; H01L 31/032; H01L 31/108

(52) U.S. Cl. CPC H01L 21/02565; H01L 21/02381; H01L 21/02458; H01L 21/02496; H01L 21/02576; H01L 21/02617; H01L 27/0629; H01L 29/24; H01L 29/78; H01L 29/812; H01L 29/872; H01L 31/032; H01L 31/108

(57) ABSTRACT

A member is provided which includes a silicon base substrate layer, a transition layer arranged over the silicon base substrate layer, and a gallium nitride (GaN) buffer layer arranged over the transition layer. The member further includes a gallium oxide layer. The member is beneficial for co-integration of ultra-wide-bandgap technology with wide bandgap technology, such as by using the gallium oxide layer with the gallium nitride buffer layer on cheap silicon substrates, such as the silicon base substrate layer. Therefore, the member provides access to establish the gallium nitride buffer layer (or gallium nitride) on the silicon base substrate layer (or silicon production lines) with improved thermal conductivity and higher electrical performance.

### CROSS-REFERENCE TO RELATED APPLICATIONS

This application is a continuation of International Application No. PCT/EP2021/070466, filed on Jul. 22, 2021, the disclosure of which is hereby incorporated by reference in its entirety.

### TECHNICAL FIELD

Embodiments of the present disclosure relate generally to the field of semiconductor devices and more specifically, to a member, transistor devices, power devices, and a method for manufacturing the member.

### BACKGROUND

Generally, a semiconductor device is based on electronic properties of a semiconductor material, such as silicon (Si), germanium (Ge), and the like, for its functioning. The semiconductor device is manufactured either as an individual device or as an integrated circuit (IC) device, such as a conventional silicon (Si)-based field-effect transistor (FET). However, due to a narrow bandgap (or energy bandgap) among the conventional Si material and a low electric field, an overall performance of the conventional Si-based FET is reduced. Conventionally, intensive efforts have been taken as a possible replacement of the conventional Si-based FET, such as by development of wide bandgap (WBG) semiconductor materials or by the development of ultrawide bandgap (UWBG) semiconductor materials. Examples of the semiconductor materials having a wide bandgap (WBG) include, but are not limited to, gallium nitride (GaN) with a bandgap of 3.4 electron volt (eV), and silicon carbide (SiC) with a bandgap of 3.3 eV. Similarly, examples of the semiconductor materials having ultrawide bandgap (UWBG) include, but are not limited to, gallium oxide (or digallium trioxide, or Ga2O3) with a bandgap of 4.9 eV, diamond with a bandgap of 5.5 eV, and aluminum nitride (AlN) with a bandgap of 6.28 eV. The semiconductor materials with the wide bandgap and the semiconductor materials with the ultrawide bandgap provides improved material properties, like larger energy bandgap, higher critical electric field, and the like. The wide bandgap semiconductor materials provide a partially improved performance both at a device level as well as at a system level, for example, conventional enhancement mode GaN and SiC power FETs are already used by semiconductor manufacturers in various products. Therefore, a significant performance improvement can be expected from the wide bandgap semiconductor materials and the ultrawide bandgap semiconductor materials over the conventional Si-based FETs. The ultrawide bandgap semiconductor materials may provide many figures-of-merit (FOM) for device performance and these FOM scales nonlinearly with the bandgap.

Typically, in high-power electronics, high power is required for power switching and to control an individual application. For example, a conventional wide bandgap semiconductor-material based FET can reduce power switching to a low level, on which heat dissipation and heat sinks will not be encumbered by a system design and can reduce an overall wastage and cost as well. Such semiconductor device can realize a stronger doping under a given breakdown voltage, which reduces the overall electric conduction and power switching. As a result, the efficiency of power transformation of such semiconductor device is increased. Conventionally, stronger doping can be realized for the semiconductor device, such as by using the silicon carbide (or vertical silicon carbide) for high breakdown voltage or by using the gallium nitride for low breakdown voltage. As far as the conventional wide bandgap technology is concerned, usually used approach for mass production of the semiconductor device for different applications is to co-integrate the gallium nitride onto a cheap silicon substrate. However, to achieve high performance semiconductor devices, it is required to co-integrate the ultrawide bandgap technology (e.g., the gallium oxide) with the gallium nitride on to cheap silicon substrate. Moreover, the usage of established gallium nitride on silicon production lines enable faster production of gallium nitride based devices. But due to low thermal conductivity associated with the gallium oxide, it is quite difficult to co-integrate the ultrawide bandgap technology (e.g., the gallium oxide) with the gallium nitride on to cheap silicon substrate. Therefore, due to the low thermal conductivity of the gallium oxide, there exists a technical problem to co-integrate the ultrawide bandgap technology (e.g., the gallium oxide) with the gallium nitride-onto cheap silicon substrate.

Therefore, in light of the foregoing discussion, there exists a need to overcome the aforementioned drawbacks associated with the conventional ultrawide bandgap technology.

### SUMMARY

Embodiments of the present disclosure provide a member, transistor devices, power devices, and a method for manufacturing the member. The present disclosure provides a solution to the existing problem to co-integrate the ultrawide bandgap technology (e.g., the gallium oxide) with the gallium nitride-on-silicon technology. An objective of the present disclosure is to provide a solution that overcomes at least partially the problems encountered in the prior art and provides an improved member, transistor devices, power devices, and further an improved method for manufacturing the member that overcomes the problems associated with the conventional ultrawide bandgap technology.

In one aspect, the present disclosure provides a member comprising a silicon base substrate layer, a transition layer arranged over the silicon base substrate layer, and a gallium nitride (GaN) buffer layer arranged over the transition layer, wherein the member further comprises a gallium oxide layer.

The member of the present disclosure implies different properties (e.g., ultrawide bandgap) of the gallium oxide layer such as to achieve benefit of higher electrical performance (e.g., breakdown voltage (BV), figures-of-merit (FOMs)) for power semiconductor devices. Beneficially, the member of the present disclosure overcomes the limitations associated with the conventional ultrawide bandgap technology, such as the disclosed member overcomes thermal limitations (e.g., low thermal conductivity) associated with a conventional gallium oxide layer by transfer of an active area of the gallium oxide layer into the gallium nitride buffer layer (or a suited gallium nitride), and on the silicon base substrate layer (or silicon carbide (SiC) substrates). Moreover, due to the improved thermal conductivity and higher electrical performance, the member can be utilized in power devices, or in optoelectronic devices.

In an implementation form, the gallium oxide (Ga2O3) layer is deposited over the gallium nitride (GaN) buffer layer.

In this implementation, the gallium oxide layer is in direct contact with the gallium nitride buffer layer. As a result, the member overcomes the thermal limitations associated with the conventional gallium oxide layer (or ultrawide bandgap technology).

In a further implementation form, the member further comprises a passivation layer between the gallium nitride (GaN) buffer layer and the gallium oxide (Ga2O3) layer, wherein the passivation layer comprises aluminium oxide, silicon dioxide or silicon nitride.

The passivation layer prevents oxidation of the gallium nitride (GaN) buffer layer.

In a further implementation form, the gallium oxide (Ga2O3) layer is deposited on the gallium nitride (GaN) buffer layer in an opening in the passivation layer.

In this implementation, selective placement of the gallium oxide layer is performed on a foreign substrate, such as on the gallium nitride (GaN) buffer layer and the silicon base substrate layer.

In a further implementation form, the gallium oxide (Ga2O3) layer is deposited over the gallium nitride (GaN) buffer layer, by being deposited on the passivation layer.

The passivation layer allows an improved adhesion with the gallium oxide layer and also reduces possible risks of delamination.

In a further implementation form, the gallium oxide (Ga2O3) layer is deposited in an area defined by lithography etching removing at least a part of the passivation layer, wherein the gallium oxide (Ga2O3) layer is deposited on a remaining portion of the passivation layer.

In this implementation, selective placement of the gallium oxide layer is performed on the passivation layer.

In a further implementation form, the gallium oxide (Ga2O3) layer is deposited on the silicon base substrate layer through an opening in the gallium nitride (GaN) buffer layer and the transition layer.

By virtue of using the opening, the gallium oxide layer comes in direct contact with the silicon base substrate layer.

In a further implementation form, the member further comprises a passivation layer on the silicon base substrate layer.

Beneficially, the passivation layer provides electrical isolation, and an improved adhesion between the silicon base substrate layer and the gallium oxide layer and also reduces risks of delamination.

In a further implementation form, the member further comprises a p-doped gallium nitride (GaN) layer arranged between the gallium nitride (GaN) buffer layer and the gallium oxide (Ga2O3) layer.

The p-doped gallium nitride layer (or p-type doping capability of gallium nitride technology) is beneficial to overcome the current limitation associated with doping in the conventional gallium oxide layer.

In a further implementation form, the gallium oxide (Ga2O3) layer is n-doped.

By virtue of using the p-doped gallium nitride layer and the n-doped gallium oxide layer, a pn junction can be created between the p-doped gallium nitride layer and the n-doped gallium oxide layer.

In a further implementation form, the gallium oxide (Ga2O3) layer comprises an n-doped gallium oxide (Ga2O3) layer on top of a semi-insulating gallium oxide (Ga2O3) layer.

By virtue of using the n-doped gallium oxide layer and the semi-insulating gallium oxide layer, the member of the present disclosure overcomes the current limitation related to the material of the conventional gallium oxide layer in terms of doping capabilities.

In another aspect, the present disclosure provides a metal-semiconductor field-effect transistor (MESFET) device comprising a member, wherein the member further comprises source node layer, gate node layer and drain node layer are arranged over the n-doped gallium oxide (Ga2O3) layer, and wherein one ohmic contact is formed between the n-doped gallium oxide (Ga2O3) layer and the source node layer and one ohmic contact is formed between the n-doped gallium oxide (Ga2O3) layer and the drain node layer.

The metal-semiconductor field-effect transistor (MESFET) device achieves all the advantages and technical effects of the member of the present disclosure.

In another aspect, the present disclosure provides a metal-oxide-semiconductor field-effect transistor (MOSFET) device comprising a member, and wherein a source node layer, gate node layer and drain node layer are arranged over the n-doped gallium oxide (Ga2O3) layer, wherein one Ohmic contact is formed between the n-doped Ga2O3 layer and the source node layer and one ohmic contact is formed between the n-doped gallium oxide (Ga2O3) layer and the drain node layer, and wherein a dielectric layer is formed between the gate node layer and the source node layer, the n-doped gallium oxide (Ga2O3) layer, and the drain node layer.

The metal-oxide-semiconductor field-effect transistor (MOSFET) device achieves all the advantages and technical effects of the member of the present disclosure.

In a further implementation form, the present disclosure provides the member, wherein the gallium oxide (Ga2O3) layer comprises an n− (Si) doped gallium oxide (Ga2O3) layer on top of a n+(Sn) doped gallium oxide (Ga2O3) layer, and wherein an anode layer is formed over the n− (Si) doped gallium oxide (Ga2O3) layer and a cathode layer is formed under the gallium oxide (Ga2O3) layer, the member thereby forming a Schottky diode device.

The Schottky diode device achieves all the advantages and technical effects of the member of the present disclosure.

In another aspect, the present disclosure provides the member, wherein the gallium oxide (Ga2O3) layer is arranged to partially cover the p-doped gallium nitride (GaN) layer, forming an exposed area of the p-doped gallium nitride (GaN) layer, and wherein the member further comprises a cathode formed on the gallium oxide (Ga2O3) layer and one or more anodes formed on the p-doped gallium nitride (GaN) layer.

The member is beneficial to form a blind ultra violet photodetector, which achieves all the advantages and technical effects of the member of the present disclosure.

In another aspect, the present disclosure provides a power device comprising the member.

The power device achieves all the advantages and technical effects of the member of the present disclosure. Moreover, the disclosed power device provides high speed switching at reduced power consumption.

In another aspect, the present disclosure provides an optoelectronic device comprising the member.

The optoelectronic device achieves all the advantages and technical effects of the member of the present disclosure. Moreover, the disclosed optoelectronic device provides an improved optical communication.

In another aspect, the present disclosure provides a method for manufacturing a member, wherein the method comprises transferring the gallium oxide (Ga2O3) layer to the member.

The method achieves all the advantages and technical effects of the member of the present disclosure.

It is to be appreciated that all the aforementioned implementation forms can be combined.

It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIGS. 1A-1G are different schematic illustrations of a member, in accordance with various examples of the present disclosure;

FIG. 2 is a flowchart of a method for manufacturing a member, in accordance with an example of the present disclosure;

FIG. 3 is a schematic illustration of a metal-semiconductor field-effect transistor device (MESFET) device, in accordance with an example of the present disclosure;

FIGS. 4A-4C are different schematic illustrations of a metal-oxide-semiconductor field-effect transistor (MOSFET) device, in accordance with various examples of the present disclosure;

FIGS. 5A-5B are different schematic illustrations of a Schottky diode device, in accordance with various examples of the present disclosure;

FIG. 6 is a schematic illustration of a blind ultra violet (UV) photodetector, in accordance with an example of the present disclosure;

FIG. 7 is a block diagram of a power device, in accordance with an example of the present disclosure; and

FIG. 8 is a block diagram of an optoelectronic device, in accordance with an example of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

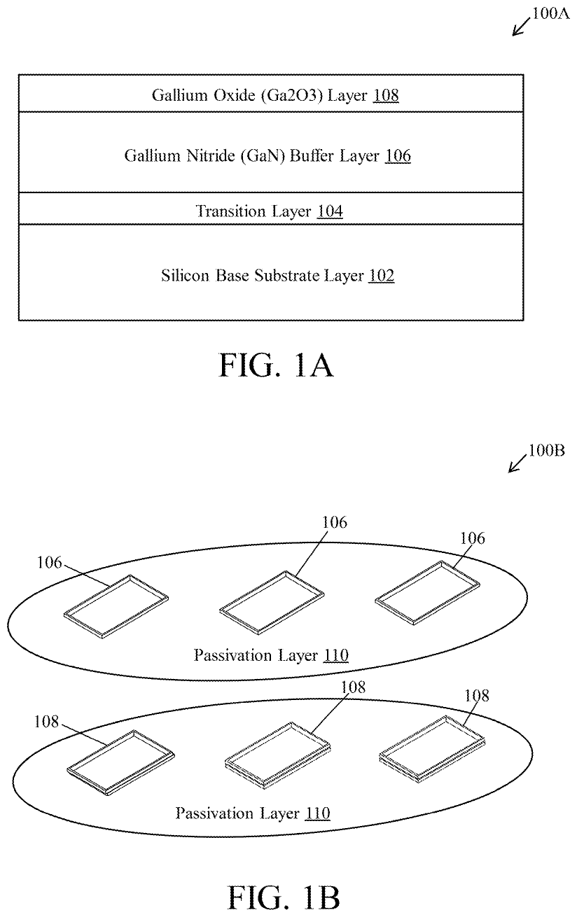

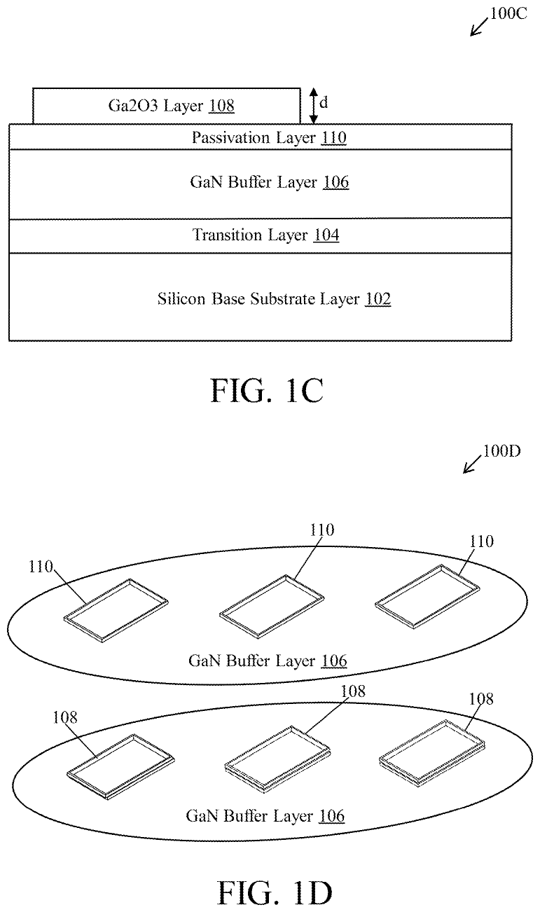

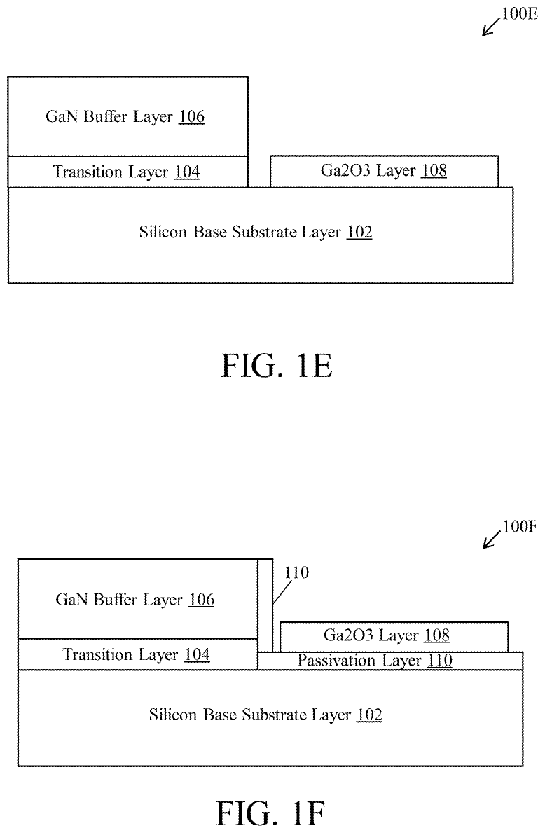

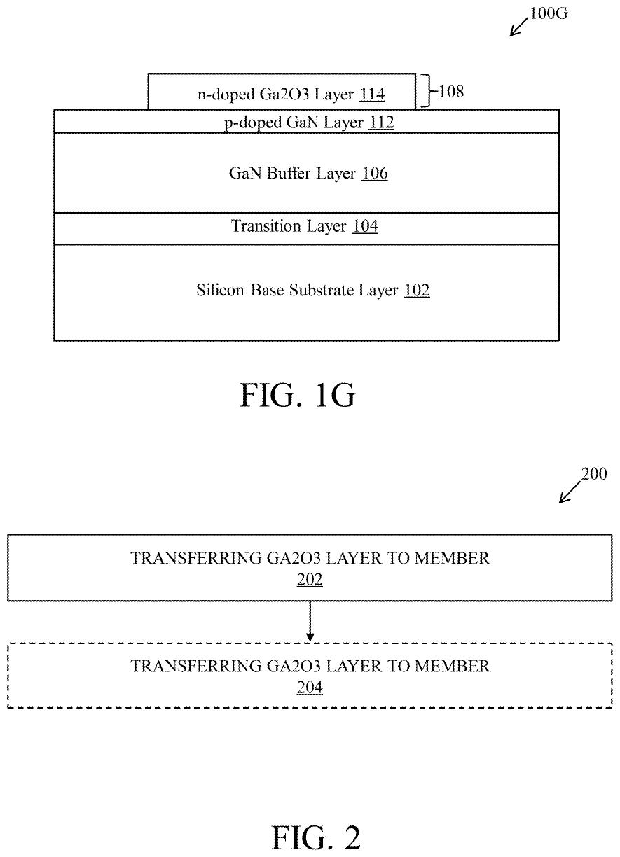

FIG. 1A is a schematic illustration of a member, in accordance with an embodiment of the present disclosure. With reference to FIG. 1A, there is shown a schematic illustration of a member 100A that includes a silicon base substrate layer 102, a transition layer 104, a gallium nitride (GaN) buffer layer 106, and a gallium oxide (Ga2O3) layer 108.

The present disclosure provides a member 100A comprising:
a silicon base substrate layer 102;
a transition layer 104 arranged over the silicon base substrate layer 102; and
a gallium nitride (GaN) buffer layer 106 arranged over the transition layer 104, wherein the member 100A further comprises a gallium oxide (Ga2O3) layer 108.

The member 100A is a semiconductor structure that includes one or more layers of semiconductor material. In an example, the semiconductor material of one layer may be same (or different) as compared to the semiconductor material of another layer. The member 100A may also comprise layers or structures of materials other than semiconductor materials. Further, the member 100A may constitute a semiconductor device or be comprised in the semiconductor device. The member 100A of the present disclosure implies co-integration of ultrawide-bandgap (UWBG) technology with wide bandgap technology, such as co-integration of the gallium oxide (Ga2O3) layer 108 to the gallium nitride buffer layer 106 on cheap silicon substrates, for example, on the silicon base substrate layer 102.

The silicon base substrate layer 102 is a thin slice of semiconductor material, which may also be referred to as a single wafer or a chip. The silicon base substrate layer 102 acts as a base of the member 100A. Due to its abundant availability, the silicon base substrate layer 102 is a low-cost material. The silicon base substrate layer 102 is available in different sizes, such as a size of six-inch (6″), eight-inch (8″), and twelve-inch (12″).

The transition layer 104 is a layer of a material (e.g., compositionally-graded materials), which is used to provide sufficient strain relief, and to limit or prevent the formation of cracks in the gallium nitride buffer layer 106.

The gallium nitride buffer layer 106 is a layer of gallium nitride semiconductor material, which is a wide-bandgap (WBG) semiconductor material. The bandgap of the gallium nitride buffer layer 106 is of a value of 3.4 electron volt (eV).

The gallium oxide (Ga2O3) layer 108 is a layer of gallium oxide semiconductor material, which is an ultra-wide bandgap (UWBG) semiconductor material. The bandgap of the gallium oxide layer 108 is of a value of 4.9 eV.

In other words, the silicon base substrate layer 102 of the member 100A acts as a base of the member 100A. Further, the transition layer 104 is deposited over the silicon base substrate layer 102. The member 100A further includes the gallium nitride buffer layer 106 arranged on the transition layer 104. In other words, the gallium nitride buffer layer 106 is arranged on the silicon base substrate layer 102, such as to form a GaN-On-Si substrate, as shown in FIG. 1A. Beneficially, the transition layer 104 provides sufficient strain relief and also limits or prevents the formation of cracks in the gallium nitride buffer layer 106. Therefore, the member 100A makes use of already existing gallium nitride (SiC or Si) technology infrastructure, such as the gallium nitride buffer layer 106 on a low cost silicon substrate, such as on the silicon base substrate layer 102. Beneficially, the member 100A makes use of consolidated gallium nitride (SiC or Si) process capabilities, such as by use of the gallium nitride buffer layer 106 in mass production of complementary metal-oxide-semiconductor (CMOS) line (e.g., of 6″ and 8″ and 12″). The member 100A further includes the gallium oxide layer 108. Therefore, the member 100A makes use of the properties of the gallium oxide layer 108 (i.e., the ultrawide bandgap semiconductor material) to achieve higher electrical performance, for example, breakdown voltage (BV), figures-of-merit (FOMs), for power semiconductor devices. Beneficially, the member 100A provides an improved thermal conductivity by transfer of an active area of the gallium oxide layer 108 into the gallium nitride buffer layer 106 (or a suited gallium nitride), and on the silicon base substrate layer 102 (or silicon carbide (SiC) substrates).

In accordance with an embodiment, the gallium oxide (Ga2O3) layer 108 is deposited over the gallium nitride (GaN) buffer layer 106. In an example, the thickness of the gallium oxide layer 108 is from nanometer (nm) to micrometer (μm). Moreover, the gallium oxide layer 108 is in direct contact with the gallium nitride buffer layer 106.

Therefore, the member 100A uses different properties (e.g., ultrawide bandgap) of the gallium oxide layer 108 so as to achieve higher electrical performance (e.g., breakdown voltage (BV), figures-of-merit (FOMs)) for power semiconductor devices. Beneficially, the member 100A overcome the limitations associated with the conventional ultrawide bandgap technology. For example, the member 100A provides an improved thermal conductivity by transfer of an active area of the gallium oxide layer 108 into the gallium nitride buffer layer 106 (or a suited gallium nitride), and on the silicon base substrate layer 102 (or silicon carbide (SiC) substrates). Moreover, due to the improved thermal conductivity, the member 100A is beneficial for utilization in a power device, or an optoelectronic device.

FIG. 1B is a schematic illustration of a member, in accordance with another embodiment of the present disclosure. FIG. 1B is described in conjunction with elements from FIG. 1A. With reference to FIG. 1B, there is shown a schematic illustration of a member 100B that includes a passivation layer 110, the gallium nitride (GaN) buffer layer 106, and the gallium oxide (Ga2O3) layer 108.

The passivation layer 110 is configured to prevent oxidation of the gallium nitride (GaN) buffer layer 106. Examples of the passivation layer 110 include, but are not limited to, a silicon dioxide (SiO2) layer, a silicon nitride (SiN) layer, or an aluminum oxide (Al2O3) layer, and the like.

In accordance with an embodiment, the gallium oxide (Ga2O3) layer 108 is deposited on the gallium nitride (GaN) buffer layer 106 in an opening in the passivation layer 110. In an example, the passivation layer 110 is initially deposited over the gallium nitride buffer layer 106. Thereafter, the passivation layer 110 is removed at few points (or places) via lithography etching, photolithography, or e-beam lithography, so as to define the opening in the passivation layer 110. Therefore, the gallium nitride buffer layer 106 is exposed through the opening, as shown in FIG. 1B. After that, the gallium oxide layer 108 is deposited in the opening and also over the gallium nitride buffer layer 106. Therefore, selective placement of the gallium oxide layer 108 is performed on a foreign substrate, such as on the gallium nitride (GaN) buffer layer 106 and the silicon base substrate layer 102.

FIG. 1C is a schematic illustration of a member, in accordance with yet another embodiment of the present disclosure. FIG. 1C is described in conjunction with elements from FIGS. 1A, and 1B. With reference to FIG. 1C, there is shown a schematic illustration of a member 100C that includes the silicon base substrate layer 102, the transition layer 104, the gallium nitride buffer layer 106, the gallium oxide layer 108, and the passivation layer 110.

In accordance with an embodiment, the member 100C comprises the passivation layer 110 between the gallium nitride (GaN) buffer layer 106 and the gallium oxide (Ga2O3) layer 108, wherein the passivation layer 110 comprises, for example, aluminium oxide, silicon dioxide or silicon nitride. It is to be understood by one of ordinary skill in the art that other material similar in properties to that of aluminium oxide, silicon dioxide or silicon nitride, may be used without limiting the scope of the disclosure. In the member 100C, the passivation layer 110 is deposited over the gallium nitride buffer layer 106. Thereafter, the gallium oxide layer 108 is deposited over the passivation layer 110. Beneficially, the passivation layer 110 prevents oxidation of the gallium nitride buffer layer 106. Examples of the passivation layer 110 include, but are not limited to, the silicon dioxide (SiO2) layer, the silicon nitride (SiN) layer, or the aluminum oxide (Al2O3) layer, and the like. In an example, the passivation layer 110 is deposited via one of a well-known possible passivation schemes, such as plasma-enhanced chemical vapor deposition (PECVD), low pressure chemical vapor deposition (LPCVP), atomic layer deposition (ALD) passivations, and the like.

In accordance with an embodiment, the gallium oxide (Ga2O3) layer 108 is deposited over the gallium nitride (GaN) buffer layer 106, by being deposited on the passivation layer 110. In the member 100C, the passivation layer 110 is deposited on the gallium nitride buffer layer 106 and results in the formation of a passivated gallium nitride. Thereafter, the gallium oxide layer 108 is deposited over the passivation layer 110, as shown in FIG. 1C. In the member 100C, pieces (e.g., with a certain area and thickness) of the gallium oxide layer 108 are deposited on the passivated gallium nitride (or aluminium gallium nitride (AlGaN)) layer. Beneficially, the passivation layer 110 allows an improved adhesion with the gallium oxide layer 108 and also reduces possible risks of delamination.

FIG. 1D is a schematic illustration of a member, in accordance with another embodiment of the present disclosure. FIG. 1D is described in conjunction with elements from FIGS. 1A, 1B, and 1C. With reference to FIG. 1D, there is shown a schematic illustration of a member 100D that includes the gallium nitride buffer layer 106, the gallium oxide layer 108, and the passivation layer 110.

In accordance with an embodiment, the gallium oxide (Ga2O3) layer 108 is deposited in an area defined by lithography etching removing at least a part of the passivation layer 110, wherein the gallium oxide (Ga2O3) layer 108 is deposited on a remaining portion of the passivation layer 110. In other words, the passivation layer 110 is initially deposited over the gallium nitride buffer layer 106. Thereafter, the lithography etching is used to define the area (or areas) where the passivation layer 110 is used as an underneath layer for deposition of the gallium oxide layer 108. Alternatively stated, the lithography etching is used to remove at least a part of the passivation layer 110 from all over the gallium nitride buffer layer 106, as shown in FIG. 1D. After that, the gallium oxide layer 108 is deposited on the remaining portion of the passivation layer 110 (e.g., over-defined passivated areas). Beneficially, the member 100D achieves a selective placement of the gallium oxide layer 108 on the passivation layer 110.

FIG. 1E is a schematic illustration of a member, in accordance with yet another embodiment of the present disclosure. FIG. 1E is described in conjunction with elements from FIGS. 1A, 1B, 1C, and 1D. With reference to FIG. 1E, there is shown a schematic illustration of a member 100E that includes the silicon base substrate layer 102, the transition layer 104, the gallium nitride buffer layer 106, and the gallium oxide layer 108.

In accordance with an embodiment, the gallium oxide (Ga2O3) layer 108 is deposited on the silicon base substrate layer 102 through an opening in the gallium nitride (GaN) buffer layer 106 and the transition layer 104. In other words, the transition layer 104 is deposited on the silicon base substrate layer 102, and the gallium nitride buffer layer 106 is deposited on the transition layer 104. Thereafter, the opening (or trench) is formed (e.g., via lithography) in the gallium nitride buffer layer 106 and also in the transition layer 104 so as to expose the silicon base substrate layer 102 underneath. Moreover, the gallium oxide layer 108 is deposited in the opening, as shown in FIG. 1E. In other words, the gallium oxide layer 108 is deposited on the silicon base substrate layer 102 (or an exposed silicon substrate). Therefore, the gallium oxide layer 108 is in direct contact with the silicon base substrate layer 102. In an implementation, the silicon base substrate layer 102 is doped via p-type doping before the deposition of the gallium oxide layer 108. In another implementation, the silicon base substrate layer 102 is doped via n-type doping before the deposition of the gallium oxide layer 108.

FIG. 1F is a schematic illustration of a member, in accordance with another embodiment of the present disclosure. FIG. 1F is described in conjunction with elements from FIGS. 1A, 1B, 1C, 1D, and 1E. With reference to FIG. 1F, there is shown a schematic illustration of a member 100F that includes the silicon base substrate layer 102, the transition layer 104, the gallium nitride buffer layer 106, the gallium oxide layer 108, and the passivation layer 110.

In accordance with an embodiment, the member 100F further comprises a passivation layer (i.e., the passivation layer 110) on the silicon base substrate layer 102. In an example, the transition layer 104 is deposited on the silicon base substrate layer 102, and the gallium nitride buffer layer 106 is deposited on the transition layer 104. Thereafter, an opening (or a trench) is formed (e.g., via lithography etching steps) in the gallium nitride buffer layer 106 and also in the transition layer 104 so as to expose the silicon base substrate layer 102 underneath. Thereafter, the passivation layer 110 is deposited in the opening on one side (e.g., vertical side) of the gallium nitride buffer layer 106, and also on one side (e.g., horizontal side) of the transition layer 104, as shown in FIG. 1F. Further, the gallium oxide layer 108 is deposited on the passivation layer 110. Therefore, the passivation layer 110 is interposed between the silicon base substrate layer 102 (or exposed silicon substrate) and the gallium oxide layer 108. Beneficially, the passivation layer 110 provides electrical isolation, and an improved adhesion between the silicon base substrate layer 102 and the gallium oxide layer 108 and also reduces risks of delamination. Additionally, the gallium oxide layer 108 can be deposited on the passivation layer 110 in a similar manner as obtained in the member 100B (of FIG. 1B) and member 100D (of FIG. 1D).

FIG. 1G is a schematic illustration of a member, in accordance with yet another embodiment of the present disclosure. FIG. 1G is described in conjunction with elements from FIGS. 1A, 1B, 1C, 1D, 1E, and 1F. With reference to FIG. 1G, there is shown a schematic illustration of a member 100G that includes a p-doped gallium nitride (GaN) layer 112, a n-doped gallium oxide (Ga2O3) layer 114, the silicon base substrate layer 102, the transition layer 104, the gallium nitride buffer layer 106, and the gallium oxide layer 108. The p-doped gallium nitride layer 112 corresponds to gallium nitride with p-type dopants, and the n-doped gallium oxide layer 114 corresponds to the gallium oxide layer 108 with n-type doping.

In accordance with an embodiment, the member 100G comprises the p-doped gallium nitride (GaN) layer 112 arranged between the gallium nitride (GaN) buffer layer 106 and the gallium oxide (Ga2O3) layer 108. In an example, the gallium nitride buffer layer 106 is deposited on the transition layer 104, and the gallium nitride buffer layer 106 is further covered by the p-doped gallium nitride layer 112. Thereafter, the gallium oxide layer 108 is deposited directly on the p-doped gallium nitride layer 112. In an example, the gallium oxide layer 108 is deposited on a selective portion of the p-doped gallium nitride layer 112. Beneficially, the member 100G makes use of the p-doped gallium nitride layer 112 (or p-type doping capability of gallium nitride technology).

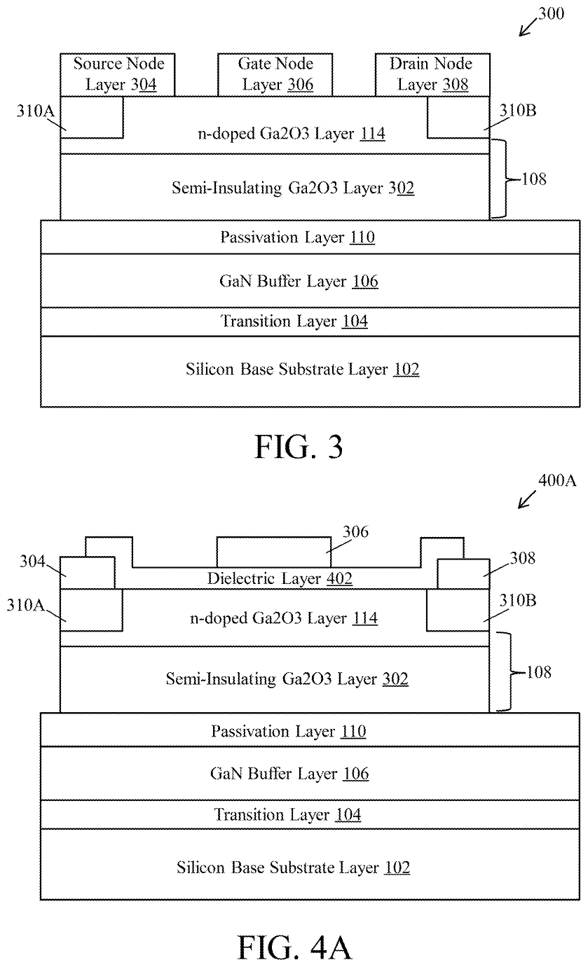

In accordance with an embodiment, the member 100G is characterized in that the gallium oxide (Ga2O3) layer 108 is n-doped. As the gallium oxide layer 108 is n-doped, such as the n-doped gallium oxide layer 114 shown in FIG. 1G. Thus a PN junction is created between the n-doped gallium oxide layer 114 and the p-doped gallium nitride layer 112 (or gallium nitride material). By virtue of using the n-doped gallium oxide layer 114, the member 100G overcomes the limitation related to material of the conventional gallium oxide layer in terms of doping capabilities. In an implementation, the gallium oxide layer 108 comprises the n-doped gallium oxide layer 114, which may be arranged over top of a semi-insulating gallium oxide layer, described in detail, for example, in FIG. 3.

FIG. 2 is a flowchart of a method for manufacturing a member, in accordance with an embodiment of the present disclosure. FIG. 2 is described in conjunction with elements from FIGS. 1A, 1B, 1C, 1D, 1E, 1F, and 1G. With reference to FIG. 2, there is shown a method 200 that includes steps 202 and 204.

The method 200 for manufacturing a member (e.g., the member 100A), wherein the method 200 comprises transferring the gallium oxide (Ga2O3) layer (i.e., the gallium oxide layer 108) to the member (e.g., the member 100A). The method 200 implies co-integration of ultrawide-bandgap (UWBG) technology with wide bandgap technology in order to improve thermal conductivity of the UWBG technology and to improve doping (p-type) capabilities of the UWBG technology. Alternatively stated, the method 200 provides co-integration of the gallium oxide (Ga2O3) layer 108 to the gallium nitride buffer layer 106 on cheap silicon substrates, for example, on the silicon base substrate layer 102 of the member 100A. The method 200 is applicable to all of the members 100A, 100B, 100C, 100D, 100E, 100F, and 100G.

At step 202, the method 200 comprises transferring the gallium oxide (Ga2O3) layer (i.e., the gallium oxide layer 108) to the member (e.g., the member 100A). For example, the member 100A includes the silicon base substrate layer 102, which acts as a base of the member 100A. Thereafter, the transition layer 104 is deposited on the silicon base substrate layer 102, and then the gallium nitride buffer layer 106 is deposited on the transition layer 104. As a result, the member 100A includes the silicon base substrate layer 102, the transition layer 104, and the gallium nitride buffer layer 106, such as forming a GaN-On-Si substrate. Additionally, the method 200 comprises, transferring the gallium oxide (Ga2O3) layer 108 to the member 100A. That means, the gallium oxide layer 108 is deposited on the gallium nitride buffer layer 106. This way, the method 200 provides co-integration of the gallium oxide (Ga2O3) layer 108 to the gallium nitride buffer layer 106 on cheap silicon substrates. Therefore, the method 200 achieves higher electrical performance (BV, FOMs) for power semiconductor devices. Beneficially, the method 200 overcome the limitations associated with the conventional ultrawide bandgap technology. For example, the method 200 overcome thermal limitations associated with the conventional gallium oxide by transferring an active area of the gallium oxide layer 108 into the gallium nitride buffer layer 106 (or a suited gallium nitride), and on the silicon base substrate layer 102 (or silicon carbide (SiC) substrates), and thus, provides improved thermal conductivity.

At step 204, the method 200 further comprises transferring the gallium oxide (Ga2O3) layer 108 to the member 100A. In an example, the transferring the gallium oxide (Ga2O3) layer 108 to the member 100A may be done using a transfer technique, such as a smart cut technique or other known techniques of transferring fine layers of crystalline material onto a mechanical support. In other words, the method 200 comprises, transfer of the very fine layers of gallium oxide layer 108 to the member 100A or deposition of the gallium oxie layer 108 on to the gallium nitride buffer layer 106 of the member 100A. Generally, the smart cut technique is a technological process that enables transferring of very fine layers of crystalline silicon material onto a mechanical support. In an implementation, the application of the smart cut technique is mainly in the production of silicon-on-insulator (SOI) wafer substrates.

In accordance with an embodiment, the method 200 further comprises transferring the gallium oxide (Ga2O3) layer 108 to the member 100A by utilizing a large area exfoliating technique. In other words, the method 200 comprises utilizing the large area exfoliating technique. In an example, the large area exfoliating technique permits cleaving or mechanical exfoliation of exfoliated layers (or thin flakes), such as the exfoliated layers of the gallium oxide layer 108. The exfoliated layers of the gallium oxide layer 108 may then be transferred to any arbitrary substrates, such as on the member 100A.

In accordance with an embodiment, the method 200 further comprises transferring the gallium oxide (Ga2O3) layer 108 to the member 100A by utilizing an electrochemical etching technique. In other words, the method 200 comprises, utilizing the electrochemical or photo-electrochemical (PEC) etching technique that promotes a reaction by irradiated light having energy above bandgap and applied external bias. Therefore, the electrochemical etching technique can also be used as starting steps of the method 200 for transferring the gallium oxide layer 108 to the member 100A. Beneficially, the electrochemical etching technique is very promising for high selectivity and also for the reduced number of new defects introduced.

Therefore, the method 200 comprises, using different properties (e.g., ultrawide bandgap) of the gallium oxide layer 108 so as to achieve higher electrical performance (e.g., breakdown voltage (BV), figures-of-merit (FOMs)) for power semiconductor devices. Beneficially, the method 200 overcome the limitations associated with the conventional ultrawide bandgap technology. For example, the method 200 overcome thermal limitations (e.g., low thermal conductivity) associated with the conventional gallium oxide by transfer of an active area of the gallium oxide layer 108 on the member 100A (such as on the gallium nitride buffer layer 106 and on the silicon base substrate layer 102) and provides an improved thermal conductivity.

The steps 202, and 204 are only illustrative, and other alternatives can also be provided where one or more steps are added, one or more steps are removed, or one or more steps are provided in a different sequence without departing from the scope of the claims herein.

FIG. 3 is a schematic illustration of a metal-semiconductor field-effect transistor (MESFET) device, in accordance with an embodiment of the present disclosure. FIG. 3 is described in conjunction with elements from FIGS. 1A, 1B, 1C, 1D, 1E, 1F and 1G. With reference to FIG. 3, there is shown a schematic illustration of a metal-semiconductor field-effect transistor device 300 that includes a semi-insulating gallium oxide (Ga2O3) layer 302, a source node layer 304, a gate node layer 306, a drain node layer 308, and ohmic contacts 310A and 310B. The metal-semiconductor field-effect transistor (MESFET) device 300 further includes the member 100A, which includes the silicon base substrate layer 102, the transition layer 104, the gallium nitride buffer layer 106, the passivation layer 110, and the n-doped gallium oxide layer 114.

The MESFET device 300 is a semiconductor device, which is generally used to amplify or switch electronic signals. The MESFET device 300 is one of the basic building blocks of modern electronics. The MESFET device 300 is composed of semiconductor material with at least three layers (or terminals), such as the source node layer 304, the gate node layer 306, and the drain node layer 308.

The semi-insulating gallium oxide layer 302 may also be referred to as a semi-insulating substrate. In an example, the semi-insulating gallium oxide layer 302 is included by the gallium oxide layer 108 so as to stop subthreshold current. Examples of materials used for the semi-insulating gallium oxide layer 302 include but are not limited to magnesium (Mg), iron (Fe), carbon (C), and the like.

The source node layer 304, the gate node layer 306, and the drain node layer 308 corresponds to source, gate, and drain terminals of the MESFET device 300. The source node layer 304, the gate node layer 306, and the drain node layer 308 are used for connection purposes (e.g., to connect the MESFET device 300 to a power supply). Examples of metals used to arrange the source node layer 304, the gate node layer 306, and the drain node layer 308 include, but are not limited to titanium/gold (Ti/Au). In an example, platinum (Pt) metal can be used to arrange the gate node layer 306 over the n-doped gallium oxide layer 114.

The ohmic contacts 310A and 310B are used for current flow (and for further electrical connection). Examples of materials used for the formation of ohmic contacts 310A and 310B include, but not limited to titanium/gold (Ti/Au), titanium (Ti), indium (In), silver (Ag), tin (Sn), tungsten (W), molybdenum (Mo), scandium (Sc), zinc (Zn), and zirconium (Zr).

In accordance with an embodiment, the gallium oxide (Ga2O3) layer 108 comprises an n-doped gallium oxide (Ga2O3) layer 114 on top of a semi-insulating gallium oxide (Ga2O3) layer 302. The MESFET device 300 is based on the member 100A that includes the transition layer 104, such as the transition layer 104 is deposited on the silicon base substrate layer 102, and the gallium nitride buffer layer 106 that is deposited on the transition layer 104. Moreover, the gallium oxide layer 108 is deposited on the gallium nitride buffer layer 106, and the gallium oxide layer 108 further includes the semi-insulating gallium oxide layer 302 and the n-doped gallium oxide layer 114. The semi-insulating gallium oxide layer 302 is deposited on the gallium nitride buffer layer 106, and the n-doped gallium oxide layer 114 is deposited on the semi-insulating gallium oxide layer 302, as shown in FIG. 3. Optionally, the member 100A of the MESFET device 300 can include the passivation layer 110 deposited on the gallium nitride buffer layer 106, and in that case, the semi-insulating gallium oxide layer 302 can be deposited on the passivation layer 110. Beneficially, the semi-insulating gallium oxide layer 302 (or a semi-insulating substrate) is included by the gallium oxide layer 108 to stop the subthreshold current. However, the MESFET device 300 can be manufactured depending on one of the members 100B, 100C, and 100D.

The metal-semiconductor field-effect transistor (MESFET) device 300 comprising a member 100A, wherein the member 100A further comprises a source node layer 304, gate node layer 306 and drain node layer 308 are arranged over the n-doped gallium oxide (Ga2O3) layer 114, and wherein one ohmic contact 310A is formed between the n-doped gallium oxide (Ga2O3) layer 114 and the source node layer 304 and one ohmic contact 310B is formed between the n-doped gallium oxide (Ga2O3) layer 114 and the drain node layer 308. In other words, the MESFET device 300 includes the member 100A, which further includes the formation of two ohmic contacts on (e.g., both sides of) the n-doped gallium oxide layer 114, which are used for current flow. Thereafter, the source node layer 304, the gate node layer 306, and the drain node layer 308 are arranged directly over the n-doped gallium oxide layer 114. As a result, the ohmic contact 310A is arranged between the n-doped gallium oxide layer 114 and the source node layer 304, and the ohmic contact 310B is arranged between the n-doped gallium oxide layer 114 and the drain node layer 308. Therefore, the MESFET device 300 is beneficial to co-integrate the n-doped gallium oxide layer 114 and the semi-insulating gallium oxide layer 302 (or the ultrawide bandgap technology) with the gallium nitride buffer layer 106 and the silicon base substrate layer 102 (or GaN-on-Si technology). Moreover, the MESFET device 300 is beneficial for high-power electronics. As the MESFET device 300 is a unipolar device because its conduction process (i.e., current flow) involves predominantly only one kind of charge carrier (i.e., either electrons or holes). Thus, the MESFET device 300 has higher switching speeds and higher operating frequencies than bipolar transistors.

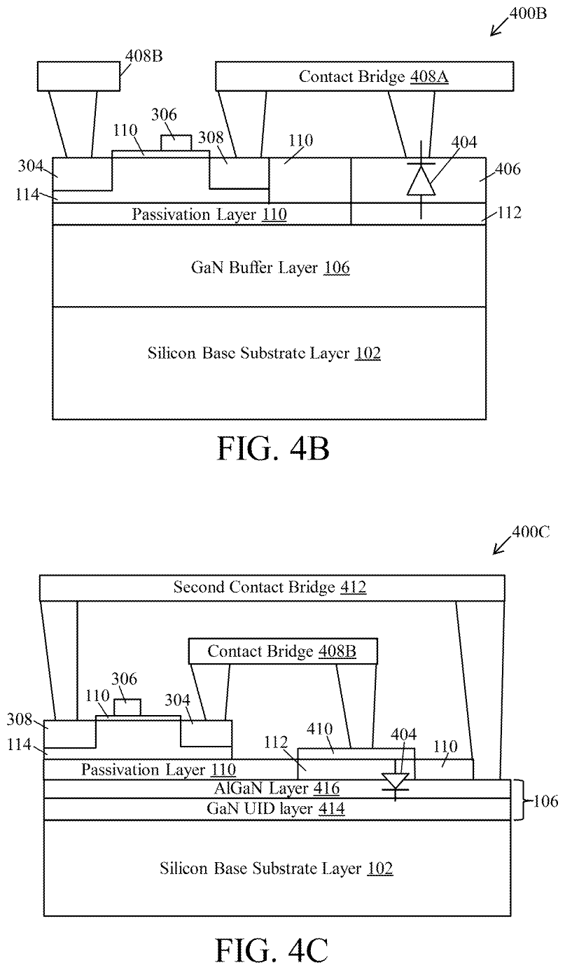

In accordance with an embodiment, a metal-semiconductor field-effect transistor (MESFET) device 300 comprising a diode, wherein the member 100A further comprises a second gallium oxide (Ga2O3) layer arranged with the p-doped gallium nitride (GaN) layer 112 being arranged under the second Ga2O3 layer, wherein the second gallium oxide (Ga2O3) layer is connected to the drain node layer 308 through a contact bridge. In an implementation, the MESFET device 300 may include the diode and for which the member 100A includes the p-doped gallium nitride layer 112 arranged on the gallium nitride buffer layer 106. The member 100A further includes the second gallium oxide layer (shown in FIG. 4B), which is arranged on the p-doped gallium nitride layer 112. The connection of the second gallium oxide layer with the p-doped gallium nitride layer 112 leads to the formation of the diode in the MESFET device 300. In addition, the contact bridge is used by the member 100A to connect the second gallium oxide layer to the drain node layer 308 of the member 100A. Therefore, the member 100A is beneficially used to fabricate a power transistor (i.e., the MESFET device 300) with an integrated body diode. In an implementation, the second gallium oxide layer is connected to the drain node layer 308 (i.e., the two contacts are connected) through via's, which can be formed on the drain node layer 308 (or an upper metalization level) in order to form a common contact.

In accordance with an embodiment, a metal-semiconductor field-effect transistor (MESFET) device 300 comprising a diode, wherein the member 100A further comprises a p-doped gallium nitride (GaN) layer 112 being arranged over the gallium nitride (GaN) buffer layer 106, wherein the p-doped gallium nitride (GaN) layer 112 is connected via an ohmic contact to the source node layer 304 through a contact bridge and wherein the gallium nitride buffer layer 106 is connected via an ohmic contact to the drain node layer 308 through a second contact bridge. In other words, the MESFET device 300 includes the diode and the member 100A. The member 100A further includes the p-doped gallium nitride layer 112 arranged on the gallium nitride buffer layer 106. In an example, the ohmic contact (not shown in FIG. 3, however, shown in FIG. 4C) is formed on the p-doped gallium nitride layer 112, and another ohmic contact (not shown in FIG. 3) is formed on the gallium nitride buffer layer 106. The ohmic contact formed on the p-doped gallium nitride layer 112 further connects the p-doped gallium nitride (GaN) layer 112 with the source node layer 304 of the member 100A through the contact bridge (not shown in FIG. 3). Alternatively, the contact bridge and the ohmic contact connect the p-doped gallium nitride (GaN) layer 112 with the source node layer 304 of the member 100A. In addition, the ohmic contact formed (not shown in FIG. 3) on the gallium nitride buffer layer 106 further connects the gallium nitride buffer layer 106 with the drain node layer 308 of the member 100A through the second contact bridge (not shown in FIG. 3). Alternatively, the second contact bridge and the ohmic contact connect the gallium nitride buffer layer 106 with the drain node layer 308 of the member 100A. Therefore, the member 100A is beneficial to fabricate a power transistor with an integrated body diode, such as to fabricate MESFET device 300 with the diode arranged between the gallium nitride buffer layer 106 and the ohmic contact.

In accordance with an embodiment, the member 100A is further characterized in that the gallium nitride (GaN) buffer layer 106 comprises an aluminium gallium nitride (AlGaN) layer on top of a gallium nitride (GaN) un-intentionally doped (UID) layer. In the MESFET device 300, the gallium nitride buffer layer 106 of the member 100A includes the aluminium gallium nitride (AlGaN) layer on top of the gallium nitride (GaN) un-intentionally doped (UID) layer. Alternatively stated, the gallium nitride un-intentionally doped layer (of the gallium nitride buffer layer 106) is directly deposited on the silicon base substrate layer 102, and the aluminium gallium nitride layer (of the gallium nitride buffer layer 106) is deposited on the gallium nitride un-intentionally doped layer. Beneficially, the aluminium gallium nitride layer of the gallium nitride buffer layer 106 provides an improved electrical connection with the drain node layer 308 of the MESFET device 300. In an implementation, a two dimensional electron gas is formed at an interface between the aluminium gallium nitride layer (AlGaN) layer and the gallium nitride un-intentionally doped layer undernearth. Moreover, the diode of the MESFET device 300 is formed between the p-doped gallium nitride layer 112 and the two dimensional electron gas.

In accordance with an embodiment, at least one of the ohmic contacts comprises titanium and/or gold. As the ohmic contacts are used for current flow and for further electrical connection purposes, thus by virtue of using the titanium and/or gold metals, an improved electrical connection is obtained through the ohmic contacts (e.g., the ohmic contacts 310A and 310B) of the member 100A.

FIG. 4A is a schematic illustration of a metal-oxide-semiconductor field-effect transistor (MOSFET) device, in accordance with an embodiment of the present disclosure. FIG. 4A is described in conjunction with elements from FIGS. 1A, 1B, 1C, 1D, 1E, 1F, 1G, and 3. With reference to FIG. 4A, there is shown a schematic illustration of a metal-oxide-semiconductor field-effect transistor (MOSFET) device 400A that includes a dielectric layer 402, the silicon base substrate layer 102, the transition layer 104, the gallium nitride buffer layer 106, the passivation layer 110, the n-doped gallium oxide layer 114, the semi-insulating gallium oxide (Ga2O3) layer 302, the source node layer 304, the gate node layer 306, the drain node layer 308, and the ohmic contacts 310A and 310B.

The MOSFET device 400A is a semiconductor device, which is generally used to amplify or switch electronic signals. The MOSFET device 400A is one of the basic building blocks of modern electronics. The MOSFET device 400A is composed of semiconductor material with different layers (or terminals), such as the source node layer 304, the gate node layer 306, the drain node layer 308, and the dielectric layer 402.

The dielectric layer 402 may also be referred to as gate dielectrics. Examples of materials used for the formation of the dielectric layer 402 include, but are not limited to, aluminium oxide (Al2O3), silicon nitride (SiN), silicon oxide (or dioxide) (SiO2), hafnium oxide (HfO2), and zirconium dioxide (ZrO2). Beneficially, the dielectric layer 402 is used to protect (or prevent oxidation of) the n-doped gallium oxide layer 114.

The present disclosure provides a metal-oxide-semiconductor field-effect transistor (MOSFET) device 400A comprising a member 100A, wherein a source node layer 304, gate node layer 306 and drain node layer 308 are arranged over the n-doped gallium oxide (Ga2O3) layer 114, wherein one ohmic contact 310A is formed between the n-doped gallium oxide (Ga2O3) layer 114 and the source node layer 304 and one ohmic contact 310B is formed between the n-doped gallium oxide (Ga2O3) layer 114 and the drain node layer 308, and wherein a dielectric layer 402 is formed between the gate node layer 306 and the source node layer 304, the n-doped gallium oxide (Ga2O3) layer 114, and the drain node layer 308. In other words, the MOSFET device 400A includes the member 100A that further includes the silicon base substrate layer 102, and the transition layer 104 that is deposited on the silicon base substrate layer 102, and the gallium nitride buffer layer 106, which is deposited on the transition layer 104. The member 100A of the MOSFET device 400A further includes the passivation layer 110, and the gallium oxide layer 108, such as the passivation layer 110 is deposited on the gallium nitride buffer layer 106, and the gallium oxide layer 108 is arranged on the passivation layer 110. In an example, the gallium oxide layer 108 further includes the semi-insulating gallium oxide layer 302 and the n-doped gallium oxide layer 114, as shown in FIG. 4A. Alternatively, the semi-insulating gallium oxide layer 302 is deposited on the gallium nitride buffer layer 106, and the n-doped gallium oxide layer 114 is deposited on the semi-insulating gallium oxide layer 302. The member 100A of the MOSFET device 400A further includes the formation of two ohmic contacts 310A and 310B on the n-doped gallium oxide layer 114, which are used for current flow. Thereafter, the source node layer 304 and the drain node layer 308 are arranged directly over the n-doped gallium oxide layer 114. As a result, one ohmic contact 310A is arranged between the n-doped gallium oxide layer 114 and the source node layer 304, and one ohmic contact 310B is arranged between the n-doped gallium oxide layer 114 and the drain node layer 308. Thereafter, the dielectric layer 402 is formed on the n-doped gallium oxide layer 114. In an example, the dielectric layer 402 is formed to partially cover the drain node layer 308 and the source node layer 304. The member 100A of the MOSFET device 400A further includes the gate node layer 306, which is arranged directly on the dielectric layer 402. For example, the gate node layer 306 is arranged on a selective area of the dielectric layer 402 (or gate dielectrics). As a result, the dielectric layer 402 of the MOSFET device 400A is formed between the gate node layer 306, the source node layer 304, the n-doped gallium oxide layer 114, and the drain node layer 308. Examples of materials used for the formation of the dielectric layer 402 include, but are not limited to, aluminium oxide (Al2O3), silicon nitride (SiN), silicon oxide (or dioxide) (SiO2), hafnium oxide (HfO2), and zirconium dioxide (ZrO2). Beneficially, the dielectric layer 402 is used to protect or prevent oxidation of the n-doped gallium oxide layer 114. Therefore, the MOSFET device 400A is beneficial to co-integrate the n-doped gallium oxide layer 114 and the semi-insulating gallium oxide layer 302 (or the ultrawide bandgap technology) with the gallium nitride buffer layer 106 and the silicon base substrate layer 102 (or GaN-on-Si technology). The MOSFET device 400A is beneficial for use in high-power electronics due to the improved thermal conductivity and higher electrical performance of the member 100A.

FIG. 4B is a schematic illustration of a metal-oxide-semiconductor field-effect transistor device, in accordance with another embodiment of the present disclosure. FIG. 4B is described in conjunction with elements from FIGS. 1A, 1B, 1C, 1D, 1E, 1F, 1G, 3, and 4A. With reference to FIG. 4B, there is shown a schematic illustration of a metal-oxide-semiconductor field-effect transistor device 400B that includes a diode 404 a second gallium oxide (Ga2O3) layer 406, a contact bridge 408A, and another contact bridge 408B. The metal-oxide-semiconductor field-effect transistor device 400B further includes the silicon base substrate layer 102, the gallium nitride buffer layer 106, the passivation layer 110, the p-doped gallium nitride layer 112, the n-doped gallium oxide layer 114, the source node layer 304, the gate node layer 306, and the drain node layer 308.

The diode 404 is a two-terminal semiconductor device that acts as a one-way switch for current flow, and may also be referred to as a body diode, integrated body diode, and the like. In general, the diode 404 allows current to flow easily in one direction but restricts the current flow in an opposite direction. The second gallium oxide layer 406 is similar to the gallium oxide layer 108.

Each of the contact bridge 408A and the other contact bridge 408B is used as an electrode contact terminal. The contact bridge 408A and the other contact bridge 408B corresponds to an aerial circuit line, such as for current transfer.

In accordance with an embodiment, a metal-oxide-semiconductor field-effect transistor (MOSFET) device 400B comprising a diode 404, wherein the member 100A further comprises a second gallium oxide (Ga2O3) layer 406 arranged with the p-doped gallium nitride (GaN) layer 112 being arranged under the second gallium oxide (Ga2O3) layer 406, wherein the second gallium oxide (Ga2O3) layer 406 is connected to the drain node layer 308 through a contact bridge 408A. In other words, the MOSFET device 400B includes the diode 404 and the member 100A. The member 100A further includes the gallium nitride buffer layer 106, which is deposited directly on the silicon base substrate layer 102. The member 100A further includes the passivation layer 110, which is deposited selectively on the gallium nitride buffer layer 106, and the n-doped gallium oxide layer 114 is also arranged selectively on the passivation layer 110. The member 100A further includes the p-doped gallium nitride layer 112 arranged selectively on a portion of the gallium nitride buffer layer 106, and the second gallium oxide layer 406 arranged on the p-doped gallium nitride layer 112. The connection of the second gallium oxide layer 406 over the p-doped gallium nitride layer 112 leads to the formation of the diode 404 in the MOSFET device 400B. In addition, the contact bridge 408A is used by the member 100A to connect the second gallium oxide layer 406 to the drain node layer 308 of the member 100A. In an example, the member 100A further uses the other contact bridge 408B to connect the source node layer 304 with the p-doped gallium nitride layer 112, as further shown and described in FIG. 4C. Therefore, the MOSFET device 400B acts as a power transistor with an integrated body diode, such as with the diode 404. Moreover, the MOSFET device 400B is beneficial for power electronics, and other such applications.

FIG. 4C is a schematic illustration of a metal-oxide-semiconductor field-effect transistor device, in accordance with yet another embodiment of the present disclosure. FIG. 4C is described in conjunction with elements from FIGS. 1A, 1B, 1C, 1D, 1E, 1F, 1G, 3, 4A, and 4B. With reference to FIG. 4C, there is shown a schematic illustration of a metal-oxide-semiconductor field-effect transistor device 400C that includes an ohmic contact 410, a second contact bridge 412, a gallium nitride (GaN) un-intentionally doped (UID) layer 414, and an aluminium gallium nitride (AlGaN) layer 416. The metal-oxide-semiconductor field-effect transistor device 400C further includes the silicon base substrate layer 102, the gallium nitride buffer layer 106, the passivation layer 110, the p-doped gallium nitride layer 112, the n-doped gallium oxide layer 114, the source node layer 304, the gate node layer 306, the drain node layer 308, the diode 404, and the other contact bridge 408B.

In accordance with an embodiment, a metal-oxide-semiconductor field-effect transistor (MOSFET) device 400C comprising a diode 404, wherein the member 100A further comprises a p-doped gallium nitride (GaN) layer 112 being arranged over the gallium nitride (GaN) buffer layer 106, wherein the p-doped gallium nitride (GaN) layer 112 is connected via an ohmic contact 410 to the source node layer 304 through a contact bridge (i.e., the other contact bridge 408B) and wherein the gallium nitride (GaN) buffer layer 106 is connected via an ohmic contact to the drain node layer 308 through a second contact bridge 412. In other words, the metal-oxide-semiconductor field-effect transistor (MOSFET) device 400C includes the diode 404 and the member 100A. The member 100A includes the gallium nitride buffer layer 106, which is deposited directly on the silicon base substrate layer 102, and the passivation layer 110, which is deposited selectively on the gallium nitride buffer layer 106. The member 100A further includes the p-doped gallium nitride layer 112 arranged on the gallium nitride buffer layer 106. The member 100A further includes the ohmic contact 410, which is formed (e.g., using deposition) on the p-doped gallium nitride layer 112. The ohmic contact 410 connects the p-doped gallium nitride (GaN) layer 112 with the source node layer 304 through the other contact bridge 408B. Alternatively, the other contact bridge 408B and the ohmic contact 410 connect the p-doped gallium nitride (GaN) layer 112 with the source node layer 304 of the MOSFET device 400C. In an example, an ohmic contact (not shown in FIG. 4C) is also formed on the gallium nitride buffer layer 106, which connects the gallium nitride buffer layer 106 with the second contact bridge 412. The second contact bridge 412 is further connected with the drain node layer 308 of the member 100A. Therefore, the member 100A of the present disclosure is beneficial to fabricate a power transistor with an integrated body diode, such as to fabricate the MOSFET device 400C with the diode 404 arranged between the gallium nitride buffer layer 106 and the ohmic contact 410.

In accordance with an embodiment, the member 100A is further characterized in that the gallium nitride (GaN) buffer layer 106 comprises a aluminium gallium nitride (AlGaN) layer 416 on top of a gallium nitride (GaN) un-intentionally doped (UID) layer 414. Alternatively stated, the gallium nitride un-intentionally doped layer 414 (of the gallium nitride buffer layer 106) is directly deposited on the silicon base substrate layer 102, and the aluminium gallium nitride layer 416 (of the gallium nitride buffer layer 106) is deposited on the gallium nitride un-intentionally doped layer 414. Beneficially, the aluminium gallium nitride layer 416 of the gallium nitride buffer layer 106 provides an improved connection with the drain node layer 308 of the member 100A through the second contact bridge 412.

In accordance with an embodiment, at least one of the ohmic contacts comprises titanium and/or gold. As the ohmic contacts are used for connection purposes, thus by virtue of using the titanium and/or gold metals, an improved connection is obtained through one of the ohmic contacts of the member 100A.

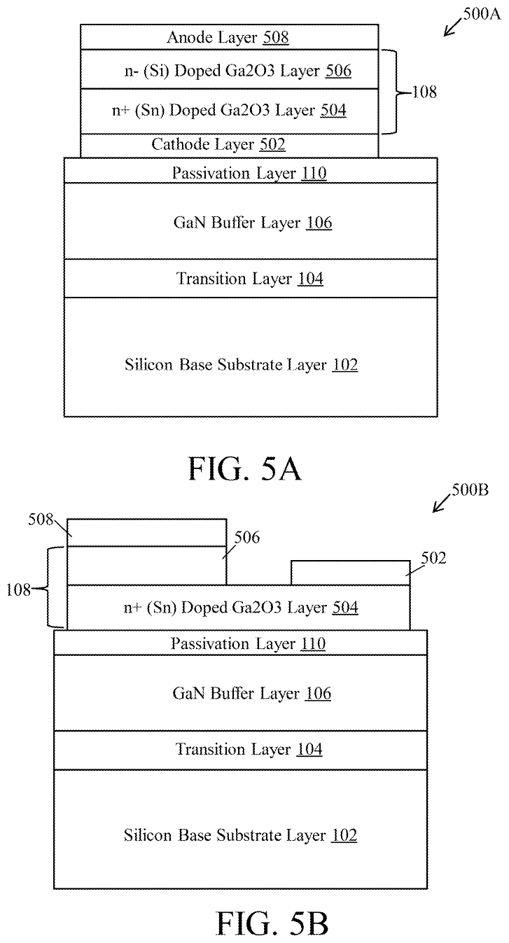

FIG. 5A is a schematic illustration of a Schottky diode device, in accordance with an embodiment of the present disclosure. FIG. 5A is described in conjunction with elements from FIGS. 1A, 1B, 1C, 1D, 1E, 1F, and 1G. With reference to FIG. 5A, there is shown a schematic illustration of a Schottky diode device 500A that includes a cathode layer 502, a n+(Sn) doped gallium oxide (Ga2O3) layer 504, a n− (Si) doped gallium oxide (Ga2O3) layer 506, and an anode layer 508. The Schottky diode device 500A further includes the silicon base substrate layer 102, the transition layer 104, the gallium nitride buffer layer 106, the gallium oxide layer 108, and the passivation layer 110.

The Schottky diode device 500A is a semiconductor diode (or a metal-semiconductor junction diode), which may also be referred to as a hot-carrier diode or Schottky barrier diode. The Schottky diode device 500A has very fast switching action, for different applications (e.g., power electronics).

The cathode layer 502 and the anode layer 508 corresponds to two terminals of the Schottky diode device 500A. In an example, the anode layer 508 is a metal side of the Schottky diode device 500A, and the cathode layer 502 is the semiconductor side of the Schottky diode device 500A. In an implementation, the anode layer 508 comprises platinum, titanium or gold, and the cathode layer 502 comprises titanium or gold metal.

The n+(Sn) doped gallium oxide (Ga2O3) layer 504 corresponds to a gallium oxide, which is doped with n+ tin (Sn), and the n− (Si) doped gallium oxide (Ga2O3) layer 506 corresponds to a gallium oxide, which is doped with n− silicon (Si).

The present disclosure provides the member 100A, wherein the gallium oxide (Ga2O3) layer 108 comprises an n− (Si) doped gallium oxide (Ga2O3) layer 506 on top of a n+(Sn) doped gallium oxide (Ga2O3) layer 504, and wherein an anode layer 508 is formed over the n− (Si) doped gallium oxide (Ga2O3) layer 506 and a cathode layer 502 is formed under the gallium oxide (Ga2O3) layer 108, the member 100A thereby forming a Schottky diode device 500A. In other words, the member 100A is included by the Schottky diode device 500A, and the member 100A includes the transition layer 104 deposited on the silicon base substrate layer 102 and the gallium nitride buffer layer 106 deposited directly on the transition layer 104. The member 100A further includes the cathode layer 502, which is formed on the gallium nitride buffer layer 106. Optionally, the passivation layer 110 can also be formed on the gallium nitride buffer layer 106, and in that case, the cathode layer 502 will be formed on the passivation layer 110, as shown in FIG. 5A. The member 100A further includes the gallium oxide layer 108 arranged on the cathode layer 502. The gallium oxide layer 108 further includes the n+(Sn) doped gallium oxide layer 504 and the n− (Si) doped gallium oxide layer 506. Such as the n+(Sn) doped gallium oxide layer 504 is deposited on the cathode layer 502, and the n− (Si) doped gallium oxide layer 506 is deposited on the n+(Sn) doped gallium oxide layer 504. Thereafter, the member 100A includes the anode layer 508, which is formed on the n− (Si) doped gallium oxide layer 506. As a result, the member 100A forms the Schottky diode device 500A, which is beneficial for high-power electronics. In an example, the Schottky diode device 500A includes a metal stack for Schottky contacts. Examples of the metals used in the metal stack for Schottky contacts include, but not limited to, nickel (Ni), platinum (Pt), palladium (Pd), tungsten (W), copper (Cu), iridium (Ir). Moreover, by virtue of using the member 100A, the Schottky diode device 500A is beneficial to co-integrate the n− (Si) doped gallium oxide layer 506 and the n+(Sn) doped gallium oxide layer 504 with the gallium nitride buffer layer 106 and the silicon base substrate layer 102 (or GaN-on-Si technology).

FIG. 5B is a schematic illustration of a Schottky diode device, in accordance with another embodiment of the present disclosure. FIG. 5B is described in conjunction with elements from FIGS. 1A, 1B, 1C, 1D, 1E, 1F, 1G, and 5A. With reference to FIG. 5B, there is shown a schematic illustration of a Schottky diode device 500B that includes the silicon base substrate layer 102, the transition layer 104, the gallium nitride buffer layer 106, the gallium oxide layer 108, and the passivation layer 110. The Schottky diode device 500B further includes the cathode layer 502, the n+(Sn) doped gallium oxide (Ga2O3) layer 504, the n− (Si) doped gallium oxide (Ga2O3) layer 506, and the anode layer 508.

In accordance with an embodiment, the gallium oxide (Ga2O3) layer 108 comprises an n− (Si) doped gallium oxide (Ga2O3) layer 506 on top of a n+(Sn) doped gallium oxide (Ga2O3) layer 504, wherein the n− (Si) doped gallium oxide (Ga2O3) layer 506 partially covering the n+(Sn) doped gallium oxide (Ga2O3) layer 504, forming an exposed area of the n+(Sn) doped gallium oxide (Ga2O3) layer 504 and wherein an anode layer 508 is formed over the n− (Si) doped gallium oxide (Ga2O3) layer 506 and a cathode layer 502 is formed over the exposed area of the n+(Sn) doped gallium oxide (Ga2O3) layer 504, the member 100A thereby forming a Schottky diode device 500B. In other words, the Schottky diode device 500B includes the member 100A, such as the member 100A further includes the transition layer 104 deposited on the silicon base substrate layer 102, and the gallium nitride buffer layer 106 deposited directly on the transition layer 104. The member 100A further includes gallium oxide layer 108, which is formed on the gallium nitride buffer layer 106. The gallium oxide layer 108 further includes the n− (Si) doped gallium oxide layer 506, and the n+(Sn) doped gallium oxide layer 504, such as the n+(Sn) doped gallium oxide layer 504 is deposited on the gallium nitride buffer layer 106, and the n− (Si) doped gallium oxide layer 506 is deposited on the n+(Sn) doped gallium oxide layer 504. Optionally, the passivation layer 110 can be formed on the gallium nitride buffer layer 106, and in that case, the n+(Sn) doped gallium oxide layer 504 is formed on the passivation layer 110, and the n− (Si) doped gallium oxide layer 506 is deposited on the n+(Sn) doped gallium oxide layer 504 as shown in FIG. 5B. In such a case, the n− (Si) doped gallium oxide layer 506 is arranged to partially cover the n+(Sn) doped gallium oxide layer 504, which results in the formation of the exposed area of the n+(Sn) doped gallium oxide layer 504. Alternatively, the n+(Sn) doped gallium oxide layer 504 is partially covered by the n− (Si) doped gallium oxide layer 506 and partially exposed so that the cathode layer 502 is formed on the exposed area of the n+(Sn) doped gallium oxide (Ga2O3) layer 504. At last, the member 100A includes the anode layer 508, which is formed on the n− (Si) doped gallium oxide layer 506 so as to reduce the overall size of the Schottky diode device 500B. Therefore, the member 100A forms the Schottky diode device 500B, which is beneficial for high-power electronics. By virtue of using the member 100A, the Schottky diode device 500B is beneficial to co-integrate the n− (Si) doped gallium oxide layer 506, and the n+(Sn) doped gallium oxide layer 504 with the gallium nitride buffer layer 106 and the silicon base substrate layer 102 (or GaN-on-Si technology).

In accordance with an embodiment, the anode layer 508 comprises platinum (Pt), titanium (Ti) or gold (Au) and the cathode layer 502 comprises titanium (Ti) or gold (Au). As the anode layer 508 and the cathode layer 502 are further used for connection purposes, such as to connect the Schottky diode device 500B to a power supply. Thus by use of the platinum, titanium or gold for the anode layer 508 and the titanium or gold medal for the cathode layer 502, an improved connection can be obtained through the anode layer 508 and the cathode layer 502.

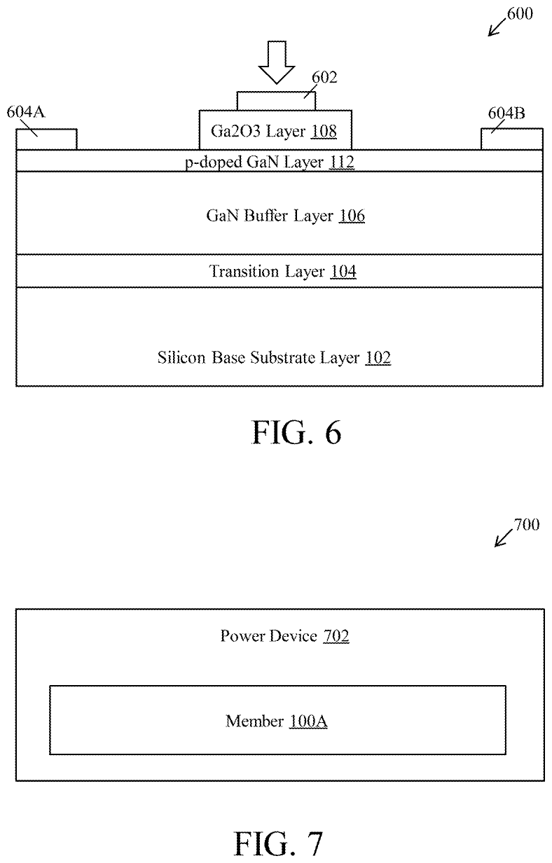

FIG. 6 is a schematic illustration of a blind ultra violet (UV) photodetector, in accordance with an embodiment of the present disclosure. FIG. 6 is described in conjunction with elements from FIGS. 1A, 1B, 1C, 1D, 1E, 1F, and 1G. With reference to FIG. 6, there is shown a schematic illustration of blind ultra violet (UV) photodetector 600 that includes a cathode 602, one or more anodes 604A and 604B, the silicon base substrate layer 102, the transition layer 104, the gallium nitride buffer layer 106, the p-doped gallium nitride layer 112, and the gallium oxide layer 108.

The blind ultra violet photodetector 600 is a semiconductor device, which is used for different applications, such as detection of ozone holes, detecting flame, space communication, missile guidance, biochemical detection, and inspection of ultra violet UV (leakage), and the like. The blind ultra violet photodetector 600 may also be referred to as a solar blind deep ultraviolet (DUV) photodetector.

The cathode 602 and one or more anodes 604A and 604B corresponds to terminals of the blind ultra violet photodetector 600, which are used for further connectivity, such as to connect the blind ultra violet photodetector 600 to a power supply.

In accordance with an embodiment, the gallium oxide (Ga2O3) layer 108 is arranged to partially cover the p-doped gallium nitride (GaN) layer 112, forming an exposed area of the p-doped gallium nitride (GaN) layer 112, and wherein the member 100A further comprises a cathode 602 formed on the gallium oxide (Ga2O3) layer 108 and one or more anodes 604A and 604B formed on the p-doped gallium nitride (GaN) layer 112. In other words, the member 100A includes the transition layer 104, which is deposited on the silicon base substrate layer 102, and the gallium nitride buffer layer 106, which is deposited directly on the transition layer 104. The member 100A further includes the p-doped gallium nitride layer 112 arranged on the gallium nitride buffer layer 106. Thereafter, the gallium oxide layer 108 is arranged on the p-doped gallium nitride layer 112, such as to partially cover the p-doped gallium nitride layer 112. In an example, the gallium oxide layer 108 is arranged at the center of the p-doped gallium nitride layer 112. The member 100A further includes the formation of the cathode 602 on the gallium oxide layer 108 and one or more anodes 604A and 604B on the p-doped gallium nitride layer 112. In an implementation, the cathode 602 formed on the gallium oxide layer 108 is a light-sensitive cathode. Therefore, the member 100A forms the blind ultra violet photodetector 600, which is beneficial for different applications, such as detection of ozone holes, detecting flame, space communication, missile guidance, biochemical detection, and inspection of ultraviolet (UV) leakage, and the like.

FIG. 7 is a block diagram of a power device, in accordance with an embodiment of the present disclosure. FIG. 7 is described in conjunction with elements from FIGS. 1A, 1B, 1C, 1D, 1E, 1F, and 1G. With reference to FIG. 7, there is shown a block diagram 700 of a power device 702 that includes the member 100A.

The power device 702 is a semiconductor device that is used as a switch or rectifier in power electronics, such as in an integrated circuit or a power integrated circuit. Examples of the power device 702 include but are not limited to a power metal-oxide-semiconductor field-effect transistor (MOSFET), a power diode, a thyristor, an insulated-gate bipolar transistor (IGBT), and the like.

The present disclosure provides a power device 702 comprising the member 100A. By virtue of using the member 100A, the power device 702 is beneficial for co-integration of ultra-wide-bandgap technology (e.g., by use of the gallium oxide (Ga2O3) layer 108 of FIG. 1A) with gallium nitride technology (i.e., gallium nitride buffer layer 106 of FIG. 1A) on cheap silicon substrates (i.e., the silicon base substrate layer 102 of FIG. 1A) of the member 100A. Moreover, the power device 702 may include one of the members 100B, 100C, 100D, 100E, 100F, and 100G (of FIGS. 1B-1G, respectively). The power device 702 may also be referred to as an opto-electronic device.

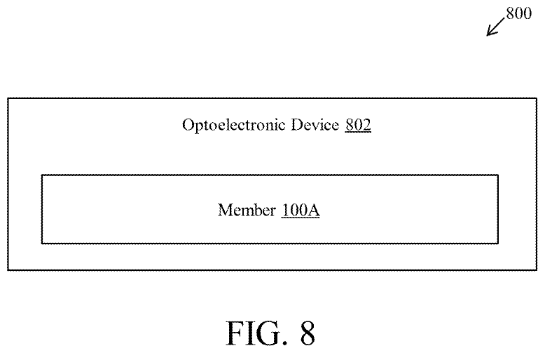

FIG. 8 is a block diagram of an optoelectronic device, in accordance with an embodiment of the present disclosure. FIG. 8 is described in conjunction with elements from FIGS. 1A, 1B, 1C, 1D, 1E, 1F, and 1G. With reference to FIG. 8, there is shown a block diagram 800 of an optoelectronic device 802 that includes the member 100A.

The optoelectronic device 802 is an electronic device that may also be referred to as an electrical-to-optical or optical-to-electrical transducer. The optoelectronic device 802 provides an improved optical communication, and examples of the optoelectronic device 802 include but are not limited to light emitted diodes, laser diodes, photodiodes, solar cells, and the like.

The present disclosure provides an optoelectronic device 802 comprising the member 100A. By virtue of using the member 100A, the optoelectronic device 802 is beneficial for co-integration of ultra-wide-bandgap technology (e.g., by use of the gallium oxide (Ga2O3) layer 108 of FIG. 1A) with gallium nitride technology (i.e., gallium nitride buffer layer 106 of FIG. 1A) on cheap silicon substrates (i.e., the silicon base substrate layer 102 of FIG. 1A) of the member 100A.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the invention, which are, for brevity, described in the context of a single embodiment, may also be provided separately or in any suitable combination or as suitable in any other described embodiment of the disclosure.

What is claimed is:

1. A member comprising:
a silicon base substrate layer;
a transition layer arranged over the silicon base substrate layer; and
a gallium nitride (GaN) buffer layer arranged over the transition layer, wherein the member further comprises a gallium oxide (Ga2O3) layer.

2. The member according to claim 1, wherein the Ga2O3 layer is deposited over the GaN buffer layer.

3. The member according to claim 2, wherein the member further comprises a passivation layer between the GaN buffer layer and the Ga2O3 layer, wherein the passivation layer comprises aluminum oxide, silicon dioxide or silicon nitride.

4. The member according to claim 3, wherein the Ga2O3 layer is deposited on the GaN buffer layer in an opening in the passivation layer.

5. The member according to claim 3, wherein the Ga2O3 layer is deposited over the GaN buffer layer, by being deposited on the passivation layer.

6. The member according to claim 3, wherein the Ga2O3 layer is deposited in an area defined by lithography etching removing at least a part of the passivation layer, wherein the Ga2O3 layer is deposited on a remaining portion of the passivation layer.

7. The member according to claim 1, wherein the Ga2O3 layer is deposited on the silicon base substrate layer through an opening in the GaN buffer layer and the transition layer.

8. The member according to claim 7, wherein the member further comprises a passivation layer on the silicon base substrate layer.

9. The member according to claim 2, wherein the member further comprises a p-doped GaN layer arranged between the GaN buffer layer and the Ga2O3 layer.

10. The member according to claim 9, wherein the Ga2O3 layer is n-doped.

11. The member according to claim 1, wherein the Ga2O3 layer comprises an n-doped Ga2O3 layer on top of a semi-insulating Ga2O3 layer.

12. A metal-semiconductor field-effect transistor (MESFET) device comprising a member according to claim 11, wherein the member further comprises:
a source node layer, gate node layer and drain node layer are arranged over the n-doped Ga2O3 layer, and wherein one ohmic contact is formed between the n-doped Ga2O3 layer and the source node layer and one ohmic contact is formed between the n-doped Ga2O3 layer and the drain node layer.

13. The device according to claim 12, further comprising a diode, wherein the member further comprises:
a second Ga2O3 layer arranged with the p-doped GaN layer being arranged under the second Ga2O3 layer, wherein the second Ga2O3 layer is connected to the drain node layer through a contact bridge.

14. The device according to claim 12, further comprising a diode, wherein the member further comprises:
a p-doped GaN layer being arranged over the GaN buffer layer, wherein the p-doped GaN layer is connected via an ohmic contact to the source node layer through a contact bridge and wherein the GaN buffer layer is connected via an ohmic contact to the drain node layer through a second contact bridge.

15. The device according to claim 12, wherein the GaN buffer layer comprises an aluminum gallium nitride (AlGaN) layer on top of a GaN un-intentionally doped (UID) layer.

16. The according to claim 12, wherein at least one of the ohmic contacts comprises titanium and/or gold.

17. A metal-oxide-semiconductor field-effect transistor (MOSFET) device comprising a member according to claim 11, and wherein a source node layer, gate node layer and drain node layer are arranged over the n-doped Ga2O3 layer, wherein
one ohmic contact is formed between the n-doped Ga2O3 layer and the source node layer and one ohmic contact is formed between the n-doped Ga2O3 layer and the drain node layer, and wherein
a dielectric layer is formed between the gate node layer and the source node layer, the n-doped Ga2O3 layer, and the drain node layer.

18. The device according to claim 17, further comprising a diode, wherein the member further comprises:
a second gallium oxide, Ga2O3, layer arranged between the GaN buffer layer and the Ga2O3 layer with the p-doped GaN layer being arranged under the second Ga2O3 layer, wherein the second Ga2O3 layer is connected to the drain node layer through a contact bridge.

19. The device according to claim 17, further comprising a diode, wherein the member further comprises:
a p-doped GaN layer being arranged over the GaN buffer layer, wherein the p-doped GaN layer is connected via an ohmic contact to the source node layer through a contact bridge, and
wherein the GaN buffer layer is connected via an ohmic contact to the drain node layer through a second contact bridge.

20. The device according to claim 18, wherein the GaN buffer layer comprises a aluminum gallium nitride (AlGaN) layer on top of a GaN un-intentionally doped (UID) layer.

21. The device according to claim 18, wherein at least one of the ohmic contacts comprises titanium and/or gold.

22. The member according to claim 1, wherein the Ga2O3 layer comprises an n− (Si) doped Ga2O3 layer on top of a n+(Sn) doped Ga2O3 layer, and wherein
an anode layer is formed over the n− (Si) doped Ga2O3 layer and
a cathode layer is formed under the Ga2O3 layer, the member thereby forming a Schottky diode device.

23. The member according to claim 1, wherein the Ga2O3 layer comprises an n− (Si) doped Ga2O3 layer on top of a n+(Sn) doped Ga2O3 layer, wherein the n− (Si) doped Ga2O3 layer partially covering the n+(Sn) doped Ga2O3 layer, forming an exposed area of the n+(Sn) doped Ga2O3 layer, and wherein
an anode layer is formed over the n− (Si) doped Ga2O3 layer, and
a cathode layer is formed over the exposed area of the n+(Sn) doped Ga2O3 layer, the member thereby forming a Schottky diode device.

24. The member according to claim 22, wherein the anode layer comprises Pt, Ti or Au, and the cathode layer comprises Ti or Au.

25. The member according to claim 9,
wherein the Ga2O3 layer is arranged to partially cover the p-doped GaN layer, forming an exposed area of the p-doped GaN layer, and
wherein the member further comprises a cathode formed on the Ga2O3 layer, and one or more anodes formed on the p-doped GaN layer.

26. A power device comprising the member according to claim 1.

27. An optoelectronic device comprising the member according to claim 1.

28. A method for manufacturing the member according to claim 1, wherein the method comprises transferring the Ga2O3 layer to the member.

29. The method according to claim 28, wherein the method further comprises transferring the Ga2O3 layer to the member by utilizing a large area exfoliating technique.

30. The method according to claim 28, wherein the method further comprises transferring the Ga2O3 layer to the member by utilizing an electrochemical etching technique.
